(19) United States
(12) Patent Application Publication
(10) Pub. No.: US 2018/0331027 A1
(43) Pub. Date: Nov. 15, 2018

(54) ELECTRONIC PACKAGE AND METHOD FOR FABRICATING THE SAME

(71) Applicant: Siliconware Precision Industries Co., Ltd., Taichung City (TW)

(72) Inventors: Jui-Feng Chen, Taichung (TW); Kai-Chang Cheng, Taichung (TW)

(21) Appl. No.: 15/663,963

(22) Filed: Jul. 31, 2017

(30) Foreign Application Priority Data
May 11, 2017 (TW) 106115597

(51) Int. Cl. H01L 23/498; H01L 23/66; H01L 23/31; H01L 21/48; H01L 21/56; H01L 23/00; H01L 21/768; H01L 21/683

(52) U.S. Cl. CPC H01L 23/49833; H01L 25/16; H01L 23/66; H01L 23/3128; H01L 21/4846; H01L 21/565; H01L 23/49816; H01L 23/49827; H01L 24/20; H01L 24/13; H01L 24/19; H01L 21/76885; H01L 24/32; H01L 21/568; H01L 21/6835; H01L 2223/6677; H01L 2221/68359; H01L 2224/211; H01L 23/49838

(57) ABSTRACT

An electronic package and a method for fabricating the same are provide. An antenna substrate is stacked on a carrier structure stacking assembly. Since no additional layout area is required to be added to the carrier structure stacking assembly, the length of an antenna can be designed as required, and the antenna can thus meet its operational requirement.

### BACKGROUND

### 1. Technical Field

The present disclosure relates to electronic packages, and, more particularly, to an electronic package with an antenna structure.

### 2. Description of Related Art

With the vigorous development of the electronics industry, electronic products are gradually moving towards providing multiple functions and high performance. At present, wireless communication technology has been widely used in a wide range of consumer electronics products for receiving or transmitting a variety of wireless signals. In order to meet the design requirements of consumer electronics products, fabricating and design of wireless communication modules are focusing on light and compact form factors, in particular, patch antenna, due to its small size, light weight and ease of fabricating, has been widely used in the wireless communication modules of mobile phones, personal digital assistant (PDA) and other electronic products.

FIG. 1 is a schematic perspective view of a conventional wireless communication module 1. The wireless communication module 1 includes a substrate 10, a plurality of electronic components 11 provided on the substrate 10, an antenna structure 12 and a packaging material 13. The substrate 10 is a circuit board and has a rectangular shape. The electronic components 11 are mounted on the substrate 10 and electrically connected to the substrate 10. The antenna structure 12 is planar and includes an antenna body 120 and a conductor 121. The antenna body 120 is electrically connected to an electronic component 11 via the conductor 121. The packaging material 13 encapsulates the electronic components 11 and a portion of the conductor 121.

However, in the conventional wireless communication module 1, the antenna structure 12 is flat, and, therefore, due to the electromagnetic radiation characteristics between the antenna structure 12 and the electronic components 11 and the volume limitation of the antenna structure 12, it is difficult to integrate the antenna body 120 with the electronic components 11 during the manufacturing process. In other words, the package material 13 encapsulates only the electronic component 11 but not the antenna body 120. As a result, the mold of the packaging process needs to be arranged with respect to the layout area of the electronic components 11 rather than the size of the substrate 10, and thus is not conducive to the packaging process.

Further, since the antenna structure 12 is flat, when the length of the antenna structure 12 needs to be increased, additional layout area (an area where the packaging material 13 is not formed) is required to be formed on the surface of the substrate 10 for forming the antenna body 120. However, the dimensions of the substrate 10 are fixed, so that it is difficult to increase the layout area, this puts limit on the length of the antenna structure 12, and thus the demand for antenna operation cannot be achieved.

Therefore, there is a need for a solution that addresses the aforementioned issues in the prior art.

### SUMMARY

In view of the aforementioned shortcomings of the prior art, the present disclosure discloses an electronic package, which may include: a carrier structure stacking assembly including a first carrier structure and a second carrier structure stacked to each other via a plurality of support members, with an electronic component provided between the first carrier structure and the second carrier structure; and an antenna substrate provided on the second carrier structure.

The present disclosure further discloses a method for fabricating an electronic package, which may include: providing a carrier structure stacking assembly including a first carrier structure and a second carrier structure stacked to each other via a plurality of support members, with an electronic component provided between the first carrier structure and the second carrier structure; and providing an antenna substrate on the second carrier structure.

In an embodiment, the step of providing the carrier structure stacking assembly may include: providing the support members and the electronic component on the first carrier structure; forming an encapsulating layer on the first carrier structure to encapsulate the electronic component and the support members; and forming a second carrier structure on the encapsulating layer, and electrically connecting the support members with the first carrier structure and the second carrier structure.

In an embodiment, the step of providing the carrier structure stacking assembly may include: providing the electronic component on the second carrier structure; and stacking the first carrier structure on the second carrier structure via the support members.

In an embodiment, the support members are electrically connected with the first carrier structure and the second carrier structure.

In an embodiment, the electronic component is electrically connected with the second carrier structure.

In an embodiment, the electronic component is an active element.

In an embodiment, the antenna substrate is formed with at least one antenna layout layer.

In an embodiment, the antenna substrate is provided on the second carrier structure through a conductive element.

In an embodiment, the antenna substrate is provided on the second carrier structure via a bonding layer.

In an embodiment, an encapsulating layer is formed between the first carrier structure and the second carrier structure to encapsulate the electronic component and the support members.

In an embodiment, an electronic device is provided on the first carrier structure.

In view of the above, the electronic package and the method for fabricating the electronic package according to the present disclosure are designed by arranging the antenna substrate on a carrier structure stacking assembly in which an electronic component is integrated. Therefore, during the manufacturing process, the encapsulating layer does not need to be cooperated with the antenna substrate, and the mold of the packaging process can correspond to the size of the first or second carrier structure of the carrier structure stacking assembly, thereby facilitating the packaging process.

Further, with the design of the antenna substrate, an additional layout area does not need to be added to the surface of the first or second carrier structure. Thus, the present disclosure is able to design the length of the antenna layout layer on the antenna substrate under a predetermined size of the first or second carrier structure, so as to achieve the demand for antenna operation, so that the electronic package can conform to the need for miniaturization.

### BRIEF DESCRIPTION OF THE DRAWINGS

FIG. 1 is a schematic perspective view of a conventional wireless communication module;

FIGS. 2A to 2F are schematic cross-sectional views illustrating a method for fabricating an electronic package in accordance with a first embodiment of the present disclosure; and

FIGS. 3A to 3F are schematic cross-sectional views illustrating a method for fabricating an electronic package in accordance with a second embodiment of the present disclosure, wherein FIG. 3C′ is a schematic cross-sectional view of another embodiment corresponding to FIG. 3C.

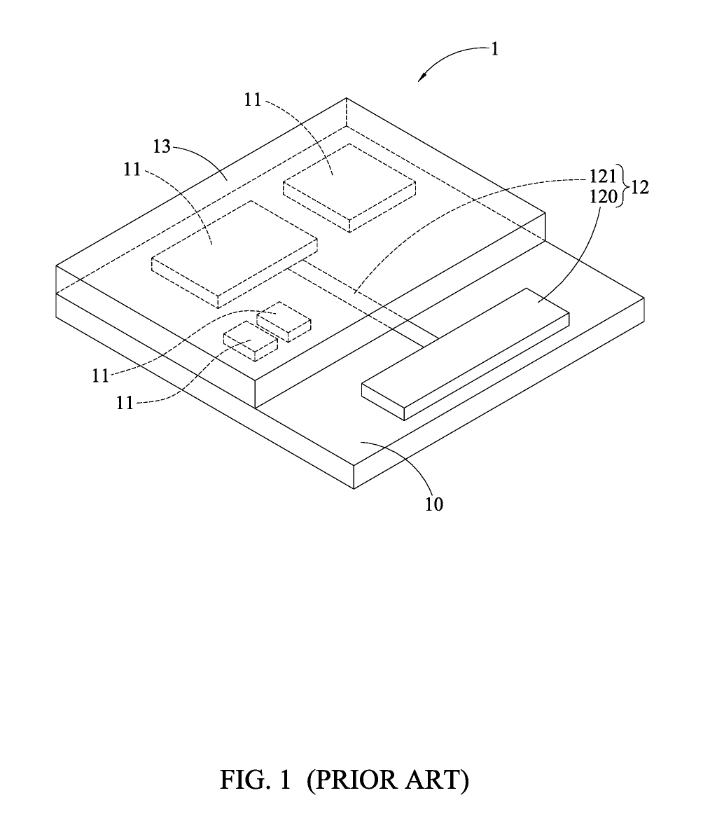

### DETAILED DESCRIPTION OF THE EMBODIMENTS

The present disclosure is described by the following specific embodiments. Those with ordinary skills in the arts can readily understand other advantages and functions of the present disclosure after reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range encapsulated by the technical contents disclosed herein. Meanwhile, terms, such as “above”, “below”, “first”, “second”, “one”, “a”, “an”, and the like, are for illustrative purposes only, and are not meant to limit the range implementable by the present disclosure. Any changes or adjustments made to their relative relationships, without modifying the substantial technical contents, are also to be construed as within the range implementable by the present disclosure.

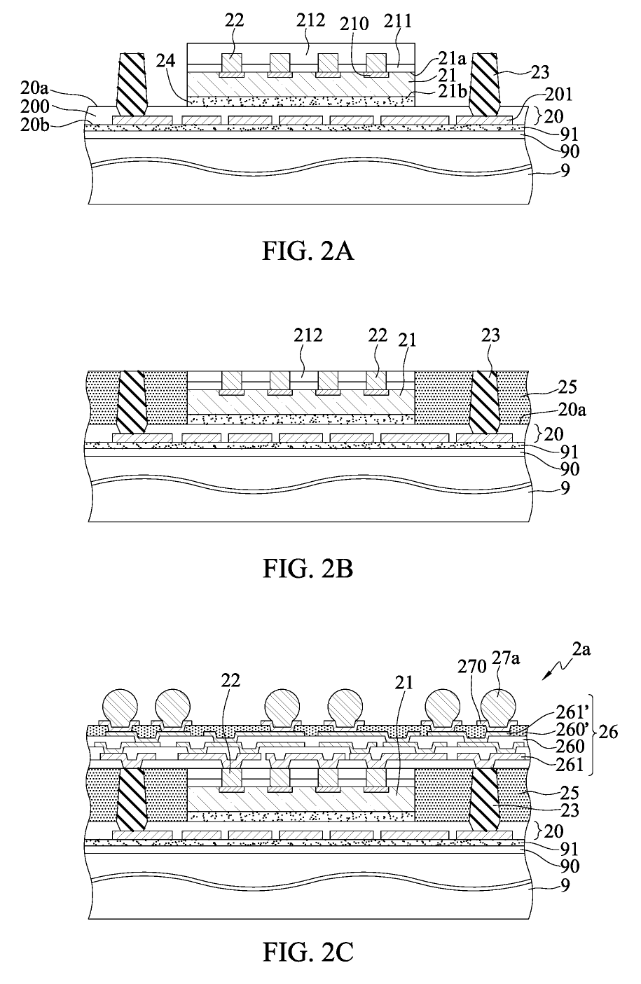

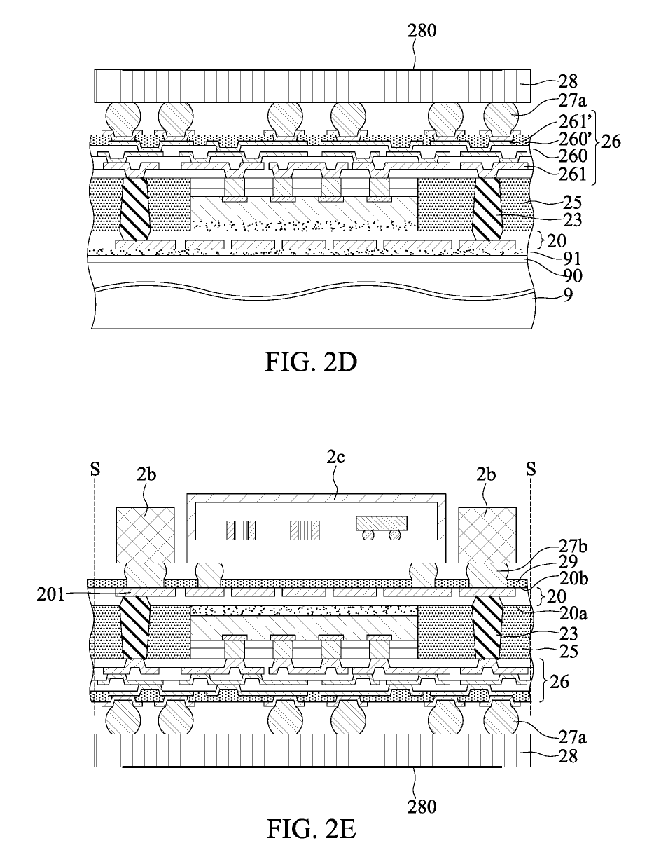

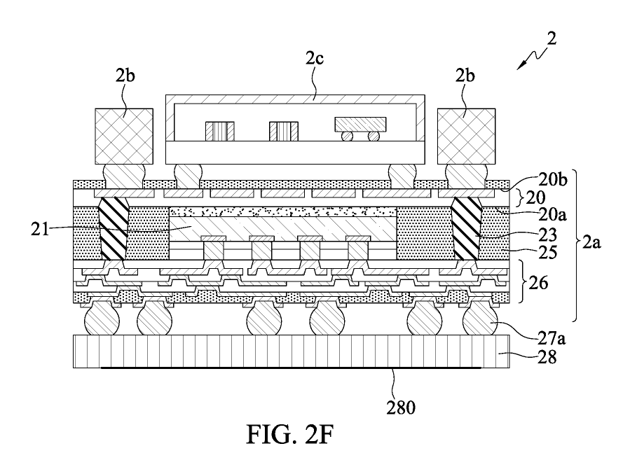

FIGS. 2A to 2F are schematic cross-sectional views illustrating a method for fabricating an electronic package 2 in accordance with a first embodiment of the present disclosure.

As shown in FIG. 2A, a carrier board 9 is provided with a first carrier structure 20. The first carrier structure 20 includes first and second sides 20a and 20b opposite to each other, and is coupled to the carrier board 9 at the second side 20. A plurality of support members 23 are electrically connected to the first carrier structure 20 and formed on the first side 20a. At least one electronic component 21 is provided on the first side 20a of the first carrier structure 20.

In an embodiment, the first carrier structure 20 is a coreless circuit structure, comprising at least one first insulating layer 200 and a first wiring layer 201 provided on the first insulating layer 200, such as redistribution layer (RDL). In an embodiment, the first wiring layer 201 can be made of copper, and the first insulating layer 200 can be made of a dielectric material, such as polybenzoxazole (PBO), polyimide (PI), prepreg (PP) and etc.

In an embodiment, the carrier board 9 is a circular plate body of a semiconductor material, such as silicon or glass, on which a release layer 90 and an adhesive layer 91 are sequentially formed by coating, such that the first carrier structure 20 can be provided on the adhesive layer 91.

In an embodiment, the support members 23 are columnar bodies, linear bodies or spherical bodies, which are provided on the first wiring layer 201 and electrically connect to the first wiring layer 201, and formed of metals, such as copper and gold, or soldering materials. In another embodiment, the support member 23 is of a wide variety and can also be, but not limited to, a passive element.

In an embodiment, the electronic component 21 is an active element, a passive element, or a combination thereof. In an embodiment, the active element is a semiconductor wafer. In an embodiment, the passive element is a resistor, a capacitor or an inductor. In an embodiment, the electronic component 21 is a semiconductor wafer having an active face 21a and a non-active face 21b. The electronic component 21 is bonded at the non-active face 21b to the first side 20a of the first carrier structure 20 via a solid crystal layer 24. A plurality of electrode pads 210 are disposed on the active face 21a. Conductive bumps 22 and two protective films 211 and 212 encapsulating the electrode pads 210 and the conductive bumps 22 are formed on the electrode pads 210. The protective films 211 and 212 can be polybenzoxazole (PBO). In an embodiment, the conductive bumps 22 can be, but not limited to, spherical of conductive circuits or solder balls; columnar made of metals, such as copper pillars or solder bumps; or stud-shaped made by a wire bonder.

As shown in FIG. 2B, an encapsulating layer 25 is formed on the first side 20a of the first carrier structure 20, and the encapsulating layer 25 encapsulates the electronic component 21 and the support members 23. After planarization, the upper protective film 212, the end faces of the support members 23 and the end faces of the conductive bumps 22 are exposed from the encapsulating layer 25, and the upper surface of the encapsulating layer 25 is flush with the upper protective film 212, the end faces of the support members 23 and the end faces of the conductive bumps 22.

In an embodiment, the encapsulating layer 25 is an insulating material, such as polyimide (PI), a dry film, an epoxy or molding compound, and can be formed on the first side 20a of the first carrier structure 20 by lamination or molding.

The planarization process can be a polishing process, in which the support members 23, the protective film 212, the conductive bumps 22 and the encapsulating layer 25 are partially removed, such that the upper surface of the encapsulating layer 25 is flush the protective film 212, the end faces of the support members 23, and the end faces of the conductive bumps 22.

As shown in FIG. 2C, a second carrier structure 26 is formed on the encapsulating layer 25, the second carrier structure 26 is stacked on the first carrier structure 20 to form a carrier structure stacking assembly 2a, and the second carrier structure 26 is electrically connected to the support members 23 and the conductive bumps 22.

In an embodiment, the second carrier structure 26 is a coreless circuit structure, including a plurality of second insulating layers 260 and 260′, and a plurality of second wiring layers 261 and 261′ (e.g., RDLs) on the second insulating layers 260 and 260′. The outermost second insulating layer 260′ serves as a solder resist, and the second outermost second wiring layer 261′ is exposed from the solder resist layer. Alternatively, the second carrier structure 26 may include only one single second insulating layer 260 and one single second wiring layer 261.

In an embodiment, the second wiring layers 261 and 261′ can be made of copper, and the second insulating layers 260 and 260′ can be made of dielectric materials, such as polybenzoxazole (PBO), polyimide (PI), prepreg Material (PP).

Further, a plurality of conductive elements 27a, such as solder balls, are disposed on the outermost second wiring layer 261′. In an embodiment, an Under Bump Metallurgy (UBM) 270 may be formed on the outermost second wiring layer 261′ to facilitate bonding of the conductive elements 27a.

As shown in FIG. 2D, an antenna substrate 28 is disposed on the conductive elements 27a.

In an embodiment, the antenna substrate 28 is of a package substrate type, and at least one antenna layout layer 280 may be formed in advance by the RDL process.

As shown in FIG. 2E, the carrier board 9 and the release layer 90 and the adhesive layer 91 thereon are removed. Thereafter, the entire structure is flipped over, and conductive elements 27b (e.g., solder balls) are then formed on the second side 20b of the first carrier structure 20, allowing an electronic device, such as at least one connector 2b or a System-in-package (SiP) package structure 2c, to be mounted thereon.

In an embodiment, an insulating protective layer 29 such as a solder resist layer is formed on the second side 20b of the first carrier structure 20, and a plurality of openings are formed in the insulating protective layer 29, so that the first wiring layer 201 is exposed to from the openings for connecting to the conductive elements 27b.

As shown in FIG. 2F, a singulation process is performed along the cutting path S shown in FIG. 2E, thereby completing the method for fabricating the electronic package 2.

In an embodiment, the carrier structure stacking assembly 2a is fabricated before the antenna substrate 28 is stacked on the second carrier structure 26 of the carrier structure stacking assembly 2a. During the fabricating process, the encapsulating layer 25 does not need to cooperate with the antenna substrate 28, so that the mold of the packaging process may correspond to the size of the first carrier structure 20, thus facilitating the packaging process.

Further, with the design of the antenna substrate 28, the antenna layout area can be designed on the antenna substrate 28 as required, so it is not necessary to increase the area on the surface of the first or second carrier structure 20 or 26. Thus, compared with the conventional technique, the method for fabricating an electronic package according to the present disclosure can design the length of the antenna layout layer 280 on the antenna substrate 28 under a predetermined size of the first or second carrier structure 20 or 26, so as to achieve the demand for antenna operation, and so that the electronic package 2 conforms to the need for miniaturization.

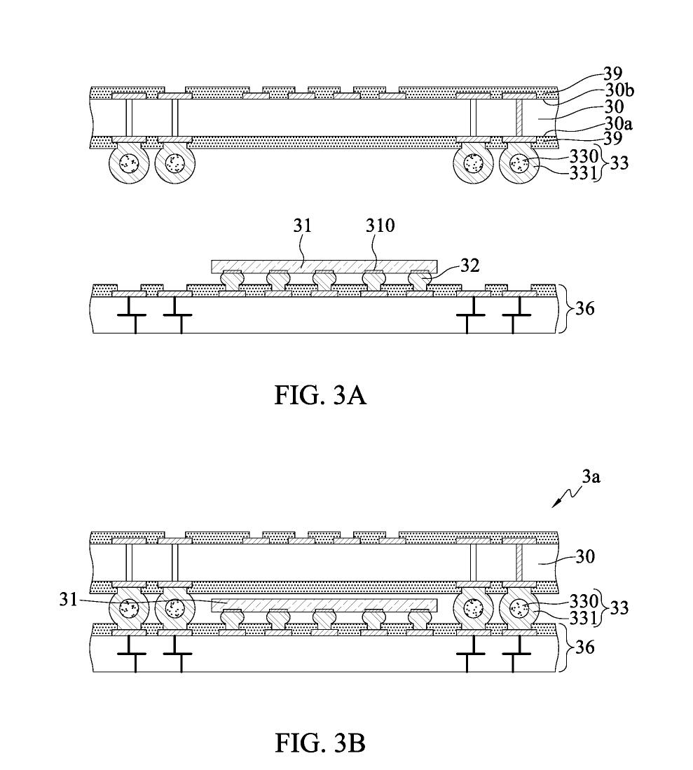

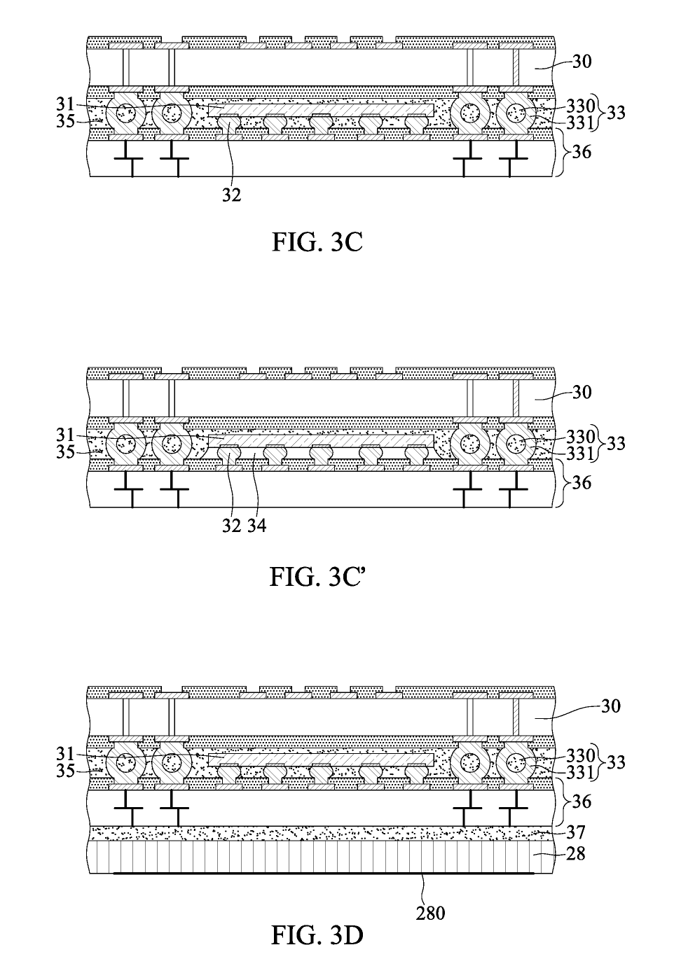

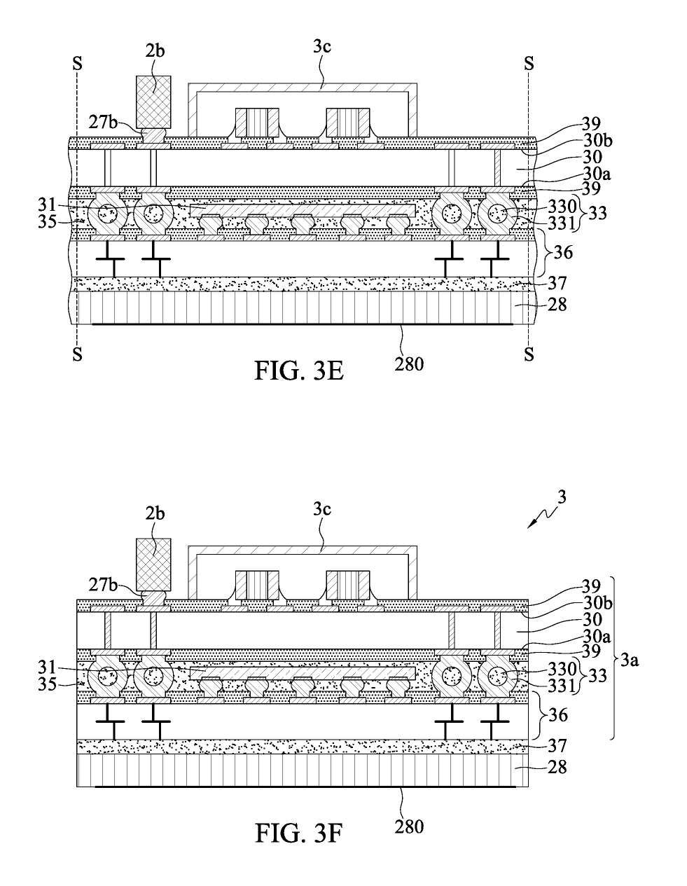

FIGS. 3A to 3F are schematic cross-sectional views illustrating a method for fabricating an electronic package 3 in accordance with a second embodiment of the present disclosure. The second embodiment and the first embodiment have different fabricating process; the constituting elements are substantially the same, so that only the differences are described below, while similar features are omitted to avoid repetition.

As shown in FIG. 3A, a first carrier structure 30 with a plurality of support members 33 and a second carrier structure 36 with an electronic component 31 are provided.

The first carrier structure 30 has a first side 30a and a second side 30b opposite to the first side 30a, and the first side 30a and the second side 30b are each formed with an insulating protective layer 39 such as a solder resist layer. In an embodiment, the first carrier structure 30 is a package substrate, including a circuit structure having a core layer or a coreless circuit structure. The circuit structure includes a dielectric layer and a wiring layer on the dielectric layer, such as fan-out RDL. In an embodiment, the dielectric layer can be made of a prepreg (PP), a polyimide (PI), an epoxy resin or a glass fiber. The wiring layer can be made of metal such as copper. In an embodiment, the first carrier structure 30 may also be other carriers for carrying a chip, such as an organic sheet, a wafer, or other carrier board with metal routings, and is not limited to the above. The carrier structure 30 is free from the carrier board 9 shown in FIG. 2A because it is a substrate itself.

In an embodiment, the second carrier structure 36 is a package substrate, including a circuit structure having a core layer or a coreless circuit structure. The circuit structure includes a dielectric layer and a wiring layer on the dielectric layer, such as fan-out RDL. In an embodiment, the dielectric layer can be made of a prepreg (PP), a polyimide (PI), an epoxy resin or a glass fiber. The wiring layer can be made of metal, such as copper. In an embodiment, the first carrier structure 36 may also be other carriers for carrying a chip, such as an organic sheet, a wafer, or other carrier board with metal routings, and is not limited to the above.

The electronic component 31 is electrically connected the second carrier structure 36 via a plurality of conductive bumps 32 in a flip chip manner through its electrode pads 310.

The support members 33 are formed on the first side 30a of the first carrier structure 30. In an embodiment, each support member 33 is composed of a plurality of materials, having a core block 330 and a conductive material 331 surrounding the core block 330. In an embodiment, the core block 330 can be made of an insulating material such as a plastic ball or a metal material such as a copper ball. The conductive material 331 is a solder material, such as nickel tin, tin lead or tin silver, but is not limited thereto. In an embodiment, the support members 33 may also be passive elements or composed of a single material, such as those shown in FIG. 2A above

As shown in FIG. 3B, the support members 33 are correspondingly coupled on the second carrier structure 36, and a reflow process is performed on the conductive materials 331, such that the first carrier structure 30 is stacked on the second carrier structure 36 to form a carrier structure stacking assembly 3a, and the electronic component 31 is disposed between the first carrier structure 30 and the second carrier structure 36.

In an embodiment, the first carrier structure 30 is electrically connected to the second carrier structure 36 through the support members 33.

As shown in FIG. 3C, an encapsulating layer 35 is formed between the first carrier structure 30 and the second carrier structure 36 and encapsulates the support members 33, the conductive bumps 32 and the electronic components 31.

In an embodiment, as shown in FIG. 3C′, it is also possible to first form an underfill 34 between the second carrier structure 36 and the electronic component 31 to encapsulate the conductive bumps 32, and then the encapsulating layer 35 is formed to encapsulate the support members 33, the underfill 34 and the electronic component 31.

As shown in FIG. 3D, an antenna substrate 28 is bonded to the second carrier structure 36 by a bonding layer 37.

As shown in FIG. 3E, a plurality of conductive members 27b such as solder balls are formed on the second side 30b of the first carrier structure 30 to receive an electronic device, such as at least one connector 2b or a system-level package (SiP) package structure 3c.

As shown in FIG. 3F, a singulation process is performed along the cutting path S shown in FIG. 3E to complete the method for fabricating the electronic package 3.

In an embodiment, the carrier structure stacking assembly 3a is fabricated before the antenna substrate 28 is stacked on the second carrier structure 36 of the carrier structure stacking assembly 3a. During the fabricating process, the encapsulating layer 35 does not need to cooperate with the antenna substrate 28, so that the mold of the packaging process may correspond to the size of the first carrier structure 30, thus facilitating the packaging process.

Further, with the design of the antenna substrate 28, the antenna layout area can be designed on the antenna substrate 28 as required, so it is not necessary to increase the area on the surface of the first or second carrier structure 30 or 36. Thus, compared with the conventional technique, the method for fabricating an electronic package according to the present disclosure can design the length of the antenna layout layer 280 on the antenna substrate 28 under a predetermined size of the first or second carrier structure 30 or 36, so as to achieve the demand for antenna operation, and so that the electronic package 3 conforms to the need for miniaturization.

The present disclosure further provides an electronic package 2, 3, which includes a carrier structure stacking assembly 2a, 3a and an antenna substrate 28.

The carrier structure stacking assembly 2a, 3a includes a first carrier structure 20, 30 and a second carrier structure 26, 36 stacked via a plurality of support members 23, 33, and at least one electronic component 21, 31 is provided between the first carrier structure 20, 30 and the second carrier structure 26, 36.

The antenna substrate 28 is stacked on the second carrier structure 26, 36.

In an embodiment, the support members 23, 33 are electrically connected with the first carrier structure 20, 30 and the second carrier structure 26, 36.

In an embodiment, the electronic component 21, 31 is electrically connected with the second carrier structure 26, 36.

In an embodiment, the electronic component 21, 31 is an active element.

In an embodiment, the antenna substrate 28 is formed with at least one antenna layout layer 280.

In an embodiment, the antenna substrate 28 is provided on the second carrier structure 26 using a conductive element 27a.

In an embodiment, the antenna substrate 28 is provided on the second carrier structure 36 using a bonding layer 37.

In an embodiment, the electronic package 2, 3 further includes an encapsulating layer 25, 35 formed between the first carrier structure 20, 30 and the second carrier structure 26, 36 and encapsulating the electronic component 21, 31 and the support members 23, 33.

In an embodiment, the electronic package 2, 3 further includes an electronic device provided on the first carrier structure 20, 30.

In view of the above, the electronic package and the method for fabricating the electronic package according to the present disclosure are mainly designed by arranging the antenna substrate on a carrier structure stacking assembly in which an electronic component is integrated, so that during the manufacturing process, the encapsulating layer does not need to be cooperate with the antenna substrate, and the mold of the packaging process can correspond to the size of the first or second carrier structure of the carrier structure stacking assembly, thereby facilitating the packaging process.

Further, with the design of the antenna substrate, additional layout area does not need to be added to the surface of the first or second carrier structure. Thus, the present disclosure is able to design the length of the antenna layout layer on the antenna substrate under a predetermined size of the first or second carrier structure, so as to achieve the demand for antenna operation, and so that the electronic package conforms to the need for miniaturization.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. An electronic package comprising:
a carrier structure stacking assembly including a first carrier structure and a second carrier structure stacked to each other via a plurality of support members, with an electronic component provided between the first carrier structure and the second carrier structure; and
an antenna substrate provided on the second carrier structure.

2. The electronic package of claim 1, wherein the support members are electrically connected with the first carrier structure and the second carrier structure.

3. The electronic package of claim 1, wherein the electronic component is electrically connected with the second carrier structure.

4. The electronic package of claim 1, wherein the electronic component is an active element.

5. The electronic package of claim 1, wherein the antenna substrate is formed with at least one antenna layout layer.

6. The electronic package of claim 1, wherein the antenna substrate is provided on the second carrier structure through a conductive element.

7. The electronic package of claim 1, wherein the antenna substrate is provided on the second carrier structure via a bonding layer.

8. The electronic package of claim 1, further comprising an encapsulating layer formed between the first carrier structure and the second carrier structure and encapsulating the electronic component and the support members.

9. The electronic package of claim 1, further comprising an electronic device provided on the first carrier structure.

10. A method for fabricating an electronic package, comprising:
providing a carrier structure stacking assembly including a first carrier structure and a second carrier structure stacked to each other via a plurality of support members, with an electronic component provided between the first carrier structure and the second carrier structure; and
providing an antenna substrate on the second carrier structure.

11. The method of claim 10, wherein providing the carrier structure stacking assembly includes:
providing the support members and the electronic component on the first carrier structure;
forming on the first carrier structure an encapsulating layer encapsulating the electronic component and the support members; and
forming the second carrier structure on the encapsulating layer, and electrically connecting the support members with the first carrier structure and the second carrier structure.

12. The method of claim 10, wherein providing the carrier structure stacking assembly includes:
providing the electronic component on the second carrier structure; and
stacking the first carrier structure on the second carrier structure via the support members.

13. The method of claim 10, wherein the support members are electrically connected with the first carrier structure and the second carrier structure.

14. The method of claim 10, wherein the electronic component is electrically connected with the second carrier structure.

15. The method of claim 10, wherein the electronic component is an active element.

16. The method of claim 10, wherein the antenna substrate is formed with at least one antenna layout layer.

17. The method of claim 10, wherein the antenna substrate is provided on the second carrier structure through a conductive element.

18. The method of claim 10, wherein the antenna substrate is provided on the second carrier structure via a bonding layer.

19. The method of claim 10, further comprising forming between the first carrier structure and the second carrier structure an encapsulating layer encapsulating the electronic component and the support members.

20. The method of claim 10, further comprising providing an electronic device on the first carrier structure.
